(19) United States
(12) Patent Application Publication
(10) Pub. No.: US 2004/0209437 A1
(43) Pub. Date: Oct. 21, 2004

(54) Method of forming a shallow trench isolation region in strained silicon layer and in an underlying on silicon - germanium layer

(75) Inventors: Hsien-Kuang Chiu, Hsinchu (TW); Fang Cheng Chen, Hsin-chu (TW); Hun-Jan Tao, Hsinchu (TW)

Correspondence Address: GEORGE O. SAILE, 28 DAVIS AVENUE, POUGHKEEPSIE, NY, 12603, US

(73) Assignee: Taiwan Semiconductor Manufacturing Co.

(21) Appl. No.: 10/417,316

(22) Filed: Apr. 16, 2003

(51) Int. Cl. H01L 21/76; H01L 21/302; H01L 21/461

(52) U.S. Cl. 438/424; 438/706; 438/713

(57) ABSTRACT

A process for forming a shallow trench isolation (STI), region in a strained silicon layer and in a top portion of an underlying, relaxed silicon-germanium layer, has been developed. The process features definition of a first opening in a silicon nitride stop layer via an anisotropic RIE procedure, using a photoresist shape as an etch mask. A following RIE procedure using HBr—Cl₂—O₂ as an etchant is next performed, defining a second opening, or a shallow trench shape opening in a strained silicon layer and in a top portion of the underlying relaxed silicon-germanium layer.

### BACKGROUND OF THE INVENTION

(1) Field of the Invention

The present invention relates to methods used to fabricate semiconductor devices, and more specifically to a method used to form a shallow trench isolation (STI), region in a strained silicon layer and in a top portion of an underlying silicon-germanium layer.

(2) Description of Prior Art

The ability to form semiconductor devices in strained silicon layers has allowed carrier mobility to be realized, thus increasing device performance. In addition the ability to form insulator filled shallow trenches has allowed the dimensions of isolation regions to be minimized, when compared to counterpart isolation regions such as thermally grown field oxide regions. The use of smaller features such as smaller isolation regions, allow a greater number of smaller semiconductor chips to be obtained from a specific size starting wafer, thus reducing the processing costs for the smaller semiconductor chip comprised with the smaller features such as shallow trench isolation (STI), regions. This invention will describe a procedure in which STI regions are formed in strained silicon-silicon germanium layers, thus allowing both reduction in semiconductor chip size, and enhanced performance resulting from devices formed in the strained silicon layer, to be realized. Prior art such as Harame et al, in U.S. Pat. No. 4,997,776, Ryum et al, in U.S. Pat. No. 6,124,614, Ek et al, in U.S. Pat. No. 5,759,898, and Chu et al, in U.S. Pat. No. 5,906,951, describe methods of forming STI regions, as well as methods of forming semiconductor devices in strained silicon layers. However none of these prior art describe the novel process sequence described in this present invention in which an STI region is formed in a strained silicon layer and in a top portion of a underlying silicon-germanium layer.

### SUMMARY OF THE INVENTION

It is an object of this invention to form a shallow trench isolation (STI) region in a strained silicon layer and in a top portion of an underlying silicon-germanium layer.

It is another object of this invention to form the STI region in the strained silicon, and in the underlying silicon-germanium layer, wherein the silicon-germanium layer is either located on a semiconductor substrate, or on a silicon on insulator (SOI), layer.

It is still another object of this invention to define the shallow trench opening for the STI region in the strained silicon layer and in a top portion of the silicon-germanium layer, using a dry etching procedure featuring a dry etch chemistry incorporating HBr, Cl₂, and O₂ as an etchant.

In accordance with the present invention a method of forming an STI region in a strained silicon layer and in a top portion of an underlying, relaxed silicon-germanium layer, is described. After growth of a relaxed silicon-germanium layer, either on a semiconductor substrate or on a silicon on insulator (SOI), layer located on the semiconductor substrate, a strained silicon layer is epitaxially grown. After deposition of a silicon nitride layer a photoresist shape is used as an etch mask to allow an anisotropic reactive ion etch (RIE), procedure to define a first opening in the silicon nitride layer exposing a portion of the top surface of the strained silicon layer. A subsequent RIE procedure, performed at a higher pressure and using a HBr—Cl₂—O₂ chemistry, is then used to define a second opening, or a shallow trench shape opening in the strained silicon layer and in a top portion of the silicon-germanium layer. After filling of the openings with a chemically vapor deposited silicon oxide layer, a chemical mechanical polishing procedure is employed to remove portions of silicon oxide from the top surface of the silicon nitride layer. Selective removal of silicon nitride results in the silicon oxide filled, STI region, located in the shallow trench shape opening.

### BRIEF DESCRIPTION OF THE DRAWINGS

The object and other advantages of this invention are best described in the preferred embodiments with reference to the attached drawings that include:

FIGS. 1-6, which schematically, in cross-sectional style, describe key stages used to form an STI region in a strained silicon layer and in a top portion of an underlying silicon-germanium layer.

### DESCRIPTION OF THE PREFERRED EMBODIMENTS

The method of forming an STI region in a strained silicon layer and in a top portion of an underlying silicon-germanium layer, will now be described in detail. Semiconductor substrate 1, comprised of P type, single crystalline silicon, featuring a <100> crystallographic orientation, is used and schematically shown in FIG. 1. Semiconductor alloy layer 2, a material with a natural lattice constant greater than that of silicon is next formed on semiconductor substrate 1. The natural lattice constant of a material is it's lattice constant in the relaxed state. Semiconductor alloy layer, a layer such as silicon-germanium, is obtained via epitaxial growth at a temperature between about 400 to 800° C., using silane, or disilane as a source for silicon, while using germane as a source for germanium. The thickness of silicon-germanium (SiGe), layer 2, is between about 3000 to 15000 Angstroms, with a fraction of germanium between about 0 to 30%. The thickness of semiconductor alloy layer 2, is chosen to insure complete covering of dislocations which can be present at the semiconductor alloy—semiconductor substrate interface. The growth conditions used result in a relaxed SiGe layer 2, on silicon semiconductor substrate 1. If desired semiconductor alloy layer 2, can be comprised of silicon-germanium-carbon, (SiGeC), again obtained via epitaxial growth conditions at a temperature between about 400 to 800° C. Silicon layer 3, is next epitaxially grown on the top surface of relaxed semiconductor alloy layer 2. Silicon layer 3, is grown at a temperature between about 400 to 800° C., using silane or disilane as a silicon source. Silicon layer 3, is grown to a thickness between about 20 to 1000 Angstroms, intentionally maintained thin to insure this layer will be comprised with the desired tensile strain. Strained silicon layer 3, is comprised with a lattice constant smaller than the lattice constant for underlying semiconductor alloy, or silicon-germanium layer 2. Strained silicon layer 3, when used to accommodate a semiconductor device such as a metal oxide semiconductor field effect transistor (MOSFET), will provide channel regions with enhanced carrier mobility when compared to counterpart channel regions formed in non-strained semiconductor material. The result of these epitaxial growth procedures is schematically shown in FIG. 1. If desired the composite layer of the strained silicon layer on the relaxed semiconductor alloy layer, can be formed on a silicon on insulator (SOI) layer, wherein the insulator component of the SOI layer is formed either in, or on the underlying semiconductor substrate.

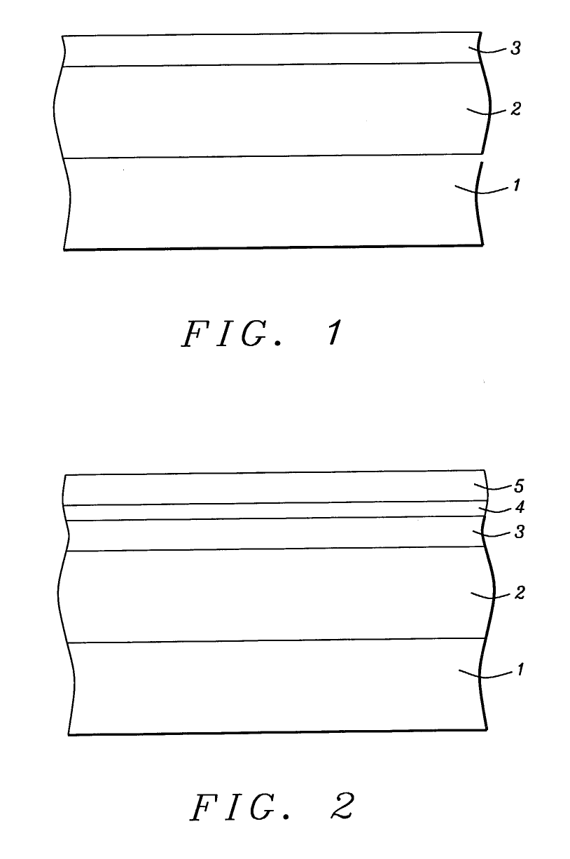

The STI region will be subsequently formed via definition of a shallow trench shape, filling of the shallow trench shape with an insulator layer, and selective removal of insulator layer from regions other than the shallow trench shape. To optimize selective removal via chemical mechanical polishing (CMP), procedures, a material resistant to the CMP procedure is used as a polishing stop material. This material can be a silicon nitride or a silicon oxynitride layer. However if desired, to avoid deposition of the polishing stop layer directly on strained silicon layer 3, a silicon oxide layer can first be formed on underlying strained silicon layer 3. FIG. 2, schematically shows silicon oxide layer 4, formed on strained silicon layer 3, via low pressure chemical vapor deposition (LPCVD), or plasma enhanced chemical vapor deposition (PECVD), procedures, using tetraethylorthosilicate (TEOS), as a source. The use of silicon oxide layer 4, is optional, with the procedure of forming an STI region in strained silicon layer 3, and in a top portion of silicon-germanium layer 2, if desired, accomplished without the employment of the silicon oxide buffer layer. Polishing stop layer 5, a silicon nitride layer, is next deposited to a thickness between about 500 to 2000 Angstroms via LPCVD or PECVD procedures, using silane, or disilane, and ammonia as reactants. This is schematically shown in FIG. 2. If desired polishing stop layer 5, can be comprised of silicon oxynitride, obtained at a thickness between about 500 to 2000 Angstroms, via LPCVD or PECVD procedures.

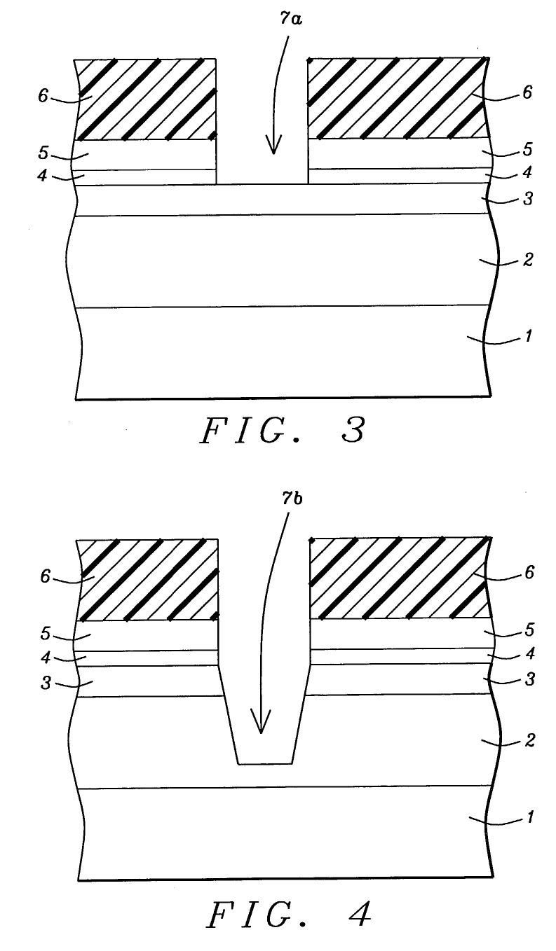

Photoresist shape 6, is formed on the top surface of polishing stop layer 5, with an opening the photoresist shape exposing a portion of the top surface of polishing stop layer 5. An anisotropic reactive ion etch (RW), procedure is next employed to transfer the opening in the photoresist shape to polishing stop layer 5, and to silicon oxide buffer layer 4. The RIE procedure is performed using Cl₂ or CF₄ for polishing stop, or silicon nitride layer 5, while CHF₃ is used as an etchant for silicon oxide layer 4. The width or diameter of opening 7a, in silicon nitride layer 5, and in silicon oxide layer 4, schematically shown in FIG. 3, is between about 0.05 to 0.25 um, with the selective RIE procedure terminating at the appearance of strained silicon layer 3. The RIE procedure is then continued, using either HBr/O_{2,}Cl_{2/}O₂, or the preferred HBr/Cl₂/O₂, as an etchant for strained silicon layer 3, and for silicon-germanium layer 2, using either He or Ar as an inert carrier gas. The RIE pressure used during the silicon and silicon-germanium etching procedure is between about 5 to 100 mtorr, resulting in a slight isotropic component, allowing shallow trench shape opening 7b, in strained silicon layer 3, and in a top portion of silicon—germanium layer 2, to be formed with a tapered sidewall. The depth of shallow trench shape opening 7b, is between about 1000 to 6000 Angstroms, the sum of the depths of the defined regions in strained silicon layer 3, and in the top portion of silicon-germanium layer 2. This is schematically shown in FIG. 4.

After removal of photoresist shape 6, via plasma oxygen ashing procedures, silicon oxide layer 8, is deposited completely filling shallow trench shape opening 7b. Silicon oxide layer 8, is obtained via LPCVD or PECVD procedures, using TEOS as a source. Silicon oxide layer in addition to filling shallow trench shape opening 7b, is also deposited on the top surface of polishing stop layer 5. If desired prior to deposition of silicon oxide layer 8, a liner layer of thermally grown silicon dioxide can be employed to coat the exposed surfaces of strained silicon layer 3, and of silicon-germanium layer 2, in shallow trench shape opening 7b. The silicon dioxide liner layer option is not shown in the drawings. A CMP procedure is next employed for planarization purposes, and to selectively remove the portions of silicon oxide layer 8, from the top surface of polishing stop layer, or silicon nitride layer 5, resulting in insulator filled, STI region 9. This is schematically shown in FIG. 5.

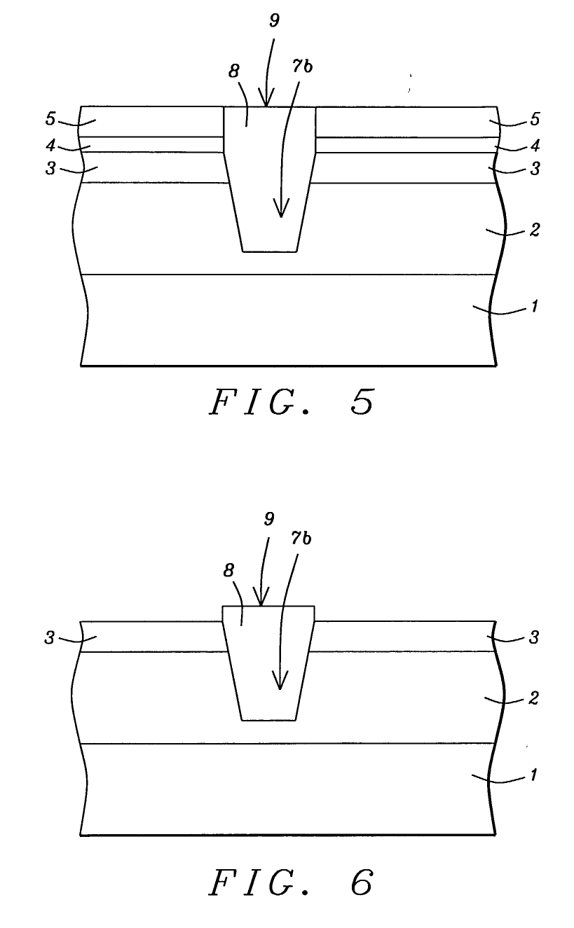

Polishing stop layer, or silicon nitride layer 5, is next selectively removed via use of a hot phosphoric acid solution, followed by removal of the optional silicon oxide buffer layer 4, via use of a buffered hydrofluoric acid solution. The fabrication procedure for STI region 9, schematically shown in FIG. 6, is now complete, with silicon oxide filled, STI region 9, located in strained silicon layer 3, and in a top portion of silicon-germanium layer 2. Subsequent formation of MOSFET devices will feature the MOSFET channel region in the strained silicon layer providing enhanced performance via enhanced carrier mobility, with isolation between elements of the MOSFET device provided by STI region 9, located in strained silicon layer 3, and in a top portion of silicon-germanium layer 2.

While this invention has been particularly shown and described with reference to the preferred embodiments thereof, it will be understood by those skilled in the art that various changes in form and details may be made without departing from the spirit and scope of this invention.

What is claimed is:

1. A method of forming a shallow trench in semiconductor materials, comprising:
providing a semiconductor substrate;
forming a semiconductor alloy layer on said semiconductor substrate;
forming a silicon layer on said semiconductor alloy layer;
forming a patterned mask layer; and
defining said shallow trench in said silicon layer and in a top portion of said semiconductor alloy layer via a dry etch procedure using an etchant including O₂ and at least one of HBr or Cl₂.

2. The method of claim 1, wherein said semiconductor alloy layer is a silicon-germanium layer, obtained via epitaxial growth procedures, at a thickness between about 3,000 to 15,000 Angstroms.

3. The method of claim 1, wherein said silicon layer is grown to a thickness between about 20 to 1,000 Angstroms.

4. The method of claim 1, wherein a polishing stop layer, selected from a group consisting of silicon nitride, silicon oxynitride, and silicon oxide, is formed on said silicon layer.

5. The method of claim 1, wherein a polishing stop layer is on said silicon layer at a thickness between about 500 to 2000 Angstroms.

6. The method of claim 1, wherein said etchant of said dry etch procedure used to define said shallow trench shape in said silicon, and in said top portion of said semiconductor alloy layer, can be comprised with an inert carrier gas such as helium or argon.

7. The method of claim 1, wherein said etchant of said dry etch procedure used to define said shallow trench shape in said silicon, and in said top portion of said semiconductor alloy layer, can be comprised with a small amount of a fluorocarbon gas.

8. The method of claim 1, wherein said dry etch procedure used to define said shallow trench shape, is performed at a pressure between about 5 to 100 mtorr.

9. The method of claim 1, wherein said shallow trench shape is defined with tapered sides.

10. A method of forming a shallow trench isolation (STI), region in a strained silicon layer and in a top portion of a relaxed silicon-germanium layer, comprising the steps of:
providing a semiconductor substrate;
growing said relaxed silicon-germanium layer on said semiconductor substrate,
growing said strained silicon layer on said relaxed silicon-germanium layer;
depositing a silicon nitride stop layer on said strained silicon layer;
using a photoresist shape as an etch mask to allow an anisotropic RIE procedure to define a first opening in said silicon nitride stop layer; and
using said photoresist shape, or said silicon nitride stop layer, as an etch mask to allow a RIE procedure to define a second opening in said strained silicon layer and in a top portion of said relaxed silicon-germanium layer.

11. The method of claim 10, wherein said semiconductor substrate is comprised of P type, single crystalline silicon, featuring a <100> crystallographic orientation.

12. The method of claim 10, wherein said semiconductor substrate is comprised with an overlying silicon on insulator (SOI), layer, wherein the insulator layer component of the SOI layer is a silicon dioxide layer, located on said semiconductor substrate.

13. The method of claim 10, wherein said relaxed silicon-germanium layer is obtained via epitaxial growth procedures.

14. The method of claim 10, wherein said relaxed silicon-germanium layer is epitaxially grown to a thickness between about 3,000 to 15,000 Angstroms.

15. The method of claim 10, wherein said strained silicon layer is obtained via epitaxial growth procedures.

16. The method of claim 10, wherein said strained silicon layer is epitaxially grown to a thickness between about 20 to 1,000 Angstroms.

17. The method of claim 10, wherein said silicon nitride stop layer is obtained via LPCVD or PECVD procedures at a thickness between about 500 to 2,000 Angstroms.

18. The method of claim 10, wherein said first opening is formed in said silicon nitride stop layer via an anisotropic RIE procedure.

19. The method of claim 10, wherein said second opening is formed in said strained silicon layer, and in a top portion of said relaxed silicon-germanium layer, via a RIE procedure, performed at a pressure between about 5 to 100 mtorr, using an etch ambient comprised of either HBr/O₂, Cl_{2/}O₂, or HBr/Cl₂/O₂.

20. The method of claim 10, wherein the width of said second opening is between about 0.05 to 0.25 um.

21. The method of claim 10, wherein the depth of said second opening in said strained silicon layer, and in a top portion of said relaxed silicon-germanium layer, is between about 3,000 to 6,000 Angstroms.

22. The method of claim 10, wherein said second opening in said strained silicon layer, and in a top portion of said relaxed silicon-germanium layer, is formed with tapered sides.
